(19) United States
(12) Patent Application Publication
(10) Pub. No.: US 2025/0167063 A1
(43) Pub. Date: May 22, 2025

(54) SEMICONDUCTOR DEVICE

(71) Applicant: Mitsubishi Electric Corporation, Tokyo (JP)

(72) Inventors: Takeshi TOKOROZUKI, Tokyo (JP); Hideo KOMO, Tokyo (JP)

(73) Assignee: Mitsubishi Electric Corporation, Tokyo (JP)

(21) Appl. No.: 18/842,384

(22) PCT Filed: Mar. 17, 2022
(86) PCT No.: PCT/JP2022/012410

§ 371 Date: Aug. 28, 2024

(51) Int. Cl. H01L 23/34; H01L 23/00; H01L 23/15; H01L 23/373; H01L 23/495; H01L 23/498; H10D 64/23

(52) U.S. Cl. CPC H01L 23/34; H01L 23/15; H01L 23/3731; H01L 23/4952; H01L 23/49568; H01L 23/49844; H01L 24/29; H01L 24/32; H10D 64/232; H01L 24/45; H01L 24/48; H01L 24/73; H01L 2224/29139; H01L 2224/32225; H01L 2224/32245; H01L 2224/45124; H01L 2224/48245; H01L 2224/73215; H01L 2224/73265; H01L 2924/10272; H01L 2924/13055

(57) ABSTRACT

A semiconductor device includes a semiconductor chip and a thermistor mounted on the semiconductor chip. The thermistor is mounted on an insulating substrate bonded to the semiconductor chip, and the semiconductor chip and the thermistor are insulated from each other by the insulating substrate. Formed on the insulating substrate is a pattern wiring leading an electrode of the thermistor outside of the thermistor in a plan view.

### TECHNICAL FIELD

The present disclosure relates to a semiconductor device.

### BACKGROUND ART

In a semiconductor device used for an inverter controlling a motor of an electrical automobile or a train or a regenerative converter, a semiconductor element generates heat due to power conduction loss, thus a thermistor for detecting a temperature is built in the semiconductor device in some cases for purposes of preventing reduction of a lifetime of the semiconductor element and protecting the semiconductor element from abnormal heat generation (for example, Patent Documents 1 and 2 hereinafter).

### PRIOR ART DOCUMENTS

### Patent Document(s)

Patent Document 1: International Publication No. 2006/068082
Patent Document 2: Japanese unexamined utility model application publication No. 01-044649

### SUMMARY

### Problem to be Solved by the Invention

In a semiconductor device in Patent Document 1, a thermistor is bonded to a main electrode of a semiconductor element by soldering. In this method, an electrode of the thermistor has potential in common with the main electrode of the semiconductor element, thus there is a problem that noise occurs in an output signal of the thermistor due to fluctuation of the potential of the main electrode occurring when current flows in the semiconductor element.

In the meanwhile, a semiconductor device in Patent Document 2, a thermistor is attached to a main electrode of a semiconductor element using an insulative adhesive agent. A thickness of the adhesive agent varies in this method, thus there is a problem in reliability of insulation, and moreover, it is difficult to perform wire bonding on the electrode of the thermistor attached to the semiconductor element.

The present disclosure is to solve the above problems, and it is an object to ensure highly reliable insulation between a thermistor and a semiconductor element in a semiconductor device including the semiconductor element provided with the thermistor, and achieve wire bonding on an electrode of the thermistor attached to the semiconductor element.

### Means to Solve the Problem

A semiconductor device according to the present disclosure includes: a semiconductor chip; and a thermistor mounted on the semiconductor chip, wherein the thermistor is mounted on an insulating substrate bonded to the semiconductor chip, and the semiconductor chip and the thermistor are insulated from each other by the insulating substrate, and formed on the insulating substrate is at least one pattern wiring leading an electrode of the thermistor outside of the thermistor in a plan view.

### Effects of the Invention

According to the present disclosure, a thickness of the insulating substrate hardly

varies, thus highly reliable insulation is ensured between the thermistor and the semiconductor element. The electrode of the thermistor is led by the pattern wiring on the insulating substrate, thus wire bonding can be performed on the electrode of the thermistor.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 A plan view of a semiconductor device according to an embodiment 1.

FIG. 2 A cross-sectional view of the semiconductor device according to the embodiment 1.

FIG. 3 A top view of a thermistor mounted on the semiconductor device according to the embodiment 1.

FIG. 4 A diagram illustrating an example of an arrangement of a first main electrode of a semiconductor chip and the thermistor.

FIG. 5 A diagram illustrating an example of an arrangement of the first main electrode of the semiconductor chip and the thermistor.

FIG. 6 A diagram illustrating an example of an arrangement of an effective region in the semiconductor chip and the thermistor.

FIG. 7 A diagram illustrating an example of an arrangement of the effective region in the semiconductor chip and the thermistor.

FIG. 8 A plan view of a semiconductor device according to an embodiment 2.

FIG. 9 A cross-sectional view of the semiconductor device according to the embodiment 2.

FIG. 10 A top view of a thermistor mounted on the semiconductor device according to the embodiment 2.

FIG. 11 A cross-sectional view of the semiconductor device according to the embodiment 2.

### DESCRIPTION OF EMBODIMENT(S)

### Embodiment 1

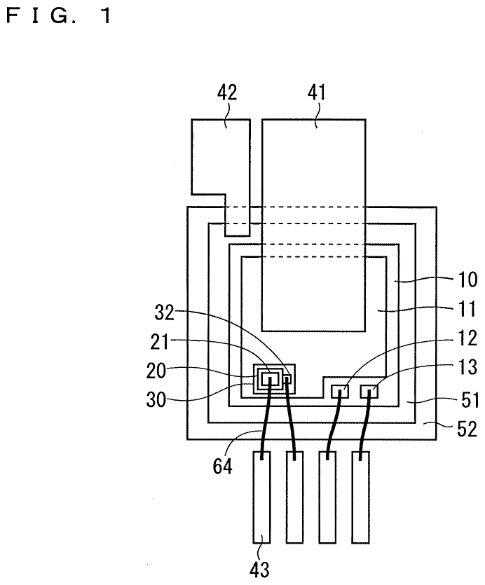

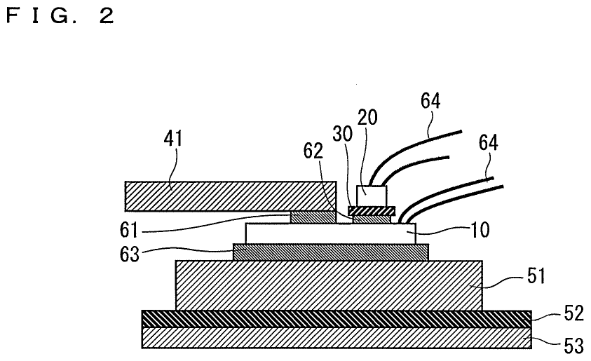

FIG. 1 and FIG. 2 are diagrams illustrating a configuration of a semiconductor device according to an embodiment 1. FIG. 1 is a plan view of the semiconductor device, and FIG. 2 is a side view of the semiconductor device. In these diagrams, illustration of molding resin sealing a constituent element of the semiconductor device is omitted.

In the semiconductor device according to the embodiment 1, a semiconductor chip 10 in which a semiconductor element is formed is mounted on a heat spreader 51, and the semiconductor chip 10 and the heat spreader 51 are bonded to each other using a solder 63 as a brazing material. The heat spreader 51 is mounted on an insulating sheet 52 having a metal foil 53 on a lower surface thereof. The semiconductor device includes, as external connection terminals, a first main terminal 41, a second main terminal 42, and a plurality of signal terminals 43.

The description herein is based on an assumption that the semiconductor element formed in the semiconductor chip 10 is an insulated gate bipolar transistor (IGBT). However, the semiconductor element formed in the semiconductor chip 10 may be the other member such as a metal oxide semiconductor field-effect transistor (MOSFET) or a diode, for example. A material of the semiconductor chip 10 may be silicon (Si) which is conventionally used or silicon carbide as wide bandgap semiconductor. When the semiconductor chip 10 is formed using SiC, a semiconductor device excellent in operation at high voltage, large current, and high temperature is obtained compared with a case of using Si.

Formed on an upper surface of the semiconductor chip 10 are a first main electrode 11 as an emitter electrode, a control electrode 12 as a gate electrode, and a sensing electrode 13 for detecting emitter current. The first main electrode 11 of the semiconductor chip 10 is bonded to a first main terminal 41 using a solder 61. The control electrode 12 and the sensing electrode 13 of the semiconductor chip 10 are each connected to a signal terminal 43 using an aluminum wire 64. A second main terminal (not shown) as a collector electrode is formed on a lower surface of the semiconductor chip 10, and the second main terminal is connected to a second main terminal 42 bonded to the heat spreader 51 via the heat spreader 51.

A thermistor 20 for detecting a temperature is mounted on the semiconductor chip 10. The thermistor 20 is mounted on an insulating substrate 30, and the insulating substrate 30 10 is bonded to the first main terminal 11 of the semiconductor chip 1 using a solder 62. That is to say, the thermistor 20 is not directly attached to the semiconductor chip 10, however, the insulating substrate 30 intervenes between the thermistor 20 and the semiconductor chip 10. A thickness of the insulating substrate 30 hardly varies, thus highly reliable insulation is ensured between the thermistor 20 and the semiconductor chip 10.

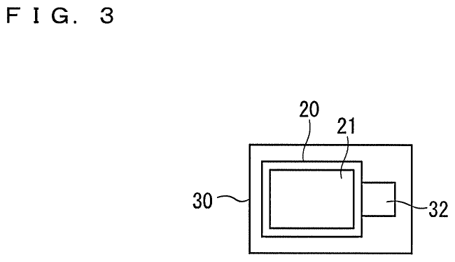

FIG. 3 illustrates an enlarged view of the thermistor 20 mounted on the insulating substrate 30. The thermistor 20 includes a first electrode 21 on an upper surface and a second electrode (not shown) on a lower surface. A pattern wiring 32 is previously formed in the insulating substrate 30 by a print technique, and the thermistor 20 is bonded to the insulating substrate 30 using a brazing material so that the second electrode on the lower surface is connected to the pattern wiring 32. Thus, the second electrode of the thermistor 20 is led outside of the thermistor 20 in a plan view by the pattern wiring 32, and wire bonding can be performed on the second electrode (that is to say, connection of the aluminum wire 64) using this pattern wiring 32 as a bonding pad. The first electrode 21 is exposed to the upper surface of the thermistor 20, thus wire bonding can be directly performed on the first electrode 21. The first electrode 21 of the thermistor 20 and the pattern wiring 32 are each connected to the signal terminal 43 using the aluminum wire 64.

The thermistor 20 and the insulating substrate 30 are preferably bonded to each other prior to the bonding of the insulating substrate 30 and the semiconductor chip 10. In this case, the thermistor 20 can be mounted on the semiconductor chip 10 only by soldering the insulating substrate 30 to the semiconductor chip 10 in a process of soldering a lead frame including the first main terminal 41 and the second main terminal 42 to the semiconductor chip 10, thus a process of assembling the semiconductor device can be simplified.

A material of the insulating substrate 30 preferable has low heat resistance so that heat generated in the semiconductor chip 10 is easily transmitted to the thermistor 20. For example, AlN which is a material having low heat resistance is used as the material of the insulating substrate 30, measurement accuracy of a temperature of the semiconductor chip 10 can be increased.

A main process in a method of manufacturing the semiconductor device according to the embodiment 1 is described herein. The method of manufacturing the semiconductor device according to the embodiment 1 includes a die bonding process, a frame bonding process, a wire bonding process, a molding process, and lead processing described hereinafter.

In the die bonding process, the semiconductor chip 10 is mounted on the heat spreader 51 using a solder 63.

In the frame bonding process, the lead frame in which the first main terminal 41, the second main terminal 42, and the signal terminal 43 are integrally formed and the insulating substrate 30 provided with the thermistor 20 are bonded to the semiconductor chip 10 using the solder 61 and the solder 62.

In the wire bonding process, the aluminum wire 64 is ultrasonic-bonded to each of the control electrode 12 and the sensing electrode 13 of the semiconductor chip 10, the first electrode 21 of the thermistor 20, the pattern wiring 32 on the insulating substrate 30, and the signal terminal 43 of the lead frame.

In the molding process, the insulating sheet 52 and a sample on which the wire bonding process has been finished are firstly placed in a cavity of a mold, and a resin pellet is set in a pot. Next, a temperature of the mold is increased, and melting resin is pressed from the pot by a plunger, and is flowed into the cavity from the gate through a runner. Subsequently, the resin is hardened under a high temperature to seal the sample.

In the lead processing process, the sample sealed by the resin is taken out of the mold, and unnecessary resin and an unnecessary part of tie-bar and the frame of the lead frame are cut by pressing to process the first main terminal 41, the second main terminal 42, and the signal terminal 43, for example, into a desired shape. The semiconductor device is thereby completed.

An operation of the semiconductor device according to the embodiment 1 is described next. When voltage is applied to the signal terminal 43 connected the control electrode 12 and the voltage between a gate and an emitter of the IGBT as the semiconductor element formed in the semiconductor chip 10 exceeds a threshold value, the IGBT enters an on state, and current flows between the first main terminal 41 and the second main terminal 42. In this time, loss caused by internal resistance of the IGBT occurs, and the semiconductor chip 10 generates heat. A signal corresponding to a temperature of the semiconductor chip 10 is outputted between the first electrode 21 and the second electrode 22 of the thermistor 20. The output signal of the thermistor 20 can be used for controlling a protection circuit protecting the semiconductor chip 10.

As described above, according to the semiconductor device of the embodiment 1, the insulating substrate 30 having little variation of thickness intervenes between the thermistor 20 and the semiconductor chip 10, thus highly reliable insulation is ensured between the thermistor 20 and the semiconductor chip 10.

The second electrode on the lower surface of the thermistor 20 is led outside of the thermistor 20 in a plan view by the pattern wiring 32 on the insulating substrate 30. When this pattern wiring 32 is used as a bonding pad, wire bonding can be performed on the second electrode of the thermistor 20 in the manner similar to the first electrode of the thermistor 20 and the control electrode 12 and the sensing electrode 13 of the semiconductor chip 10. Accordingly, wiring can be collectively performed on the plurality of signal terminals 43, thus this configuration can contribute to simplification and efficiency of an assembly process. Furthermore, the thermistor 20 and the insulating substrate 30 can also be inspected before being attached to the semiconductor chip 10, thus this configuration leads to reduction of loss cost.

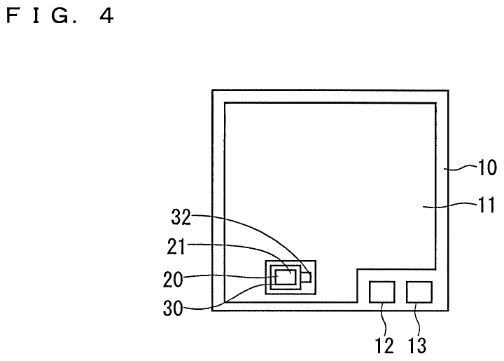

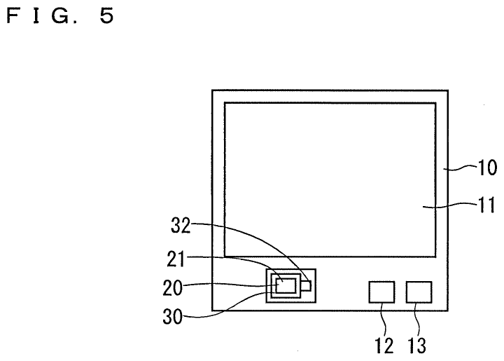

The thermistor 20 is insulated from the semiconductor chip 10 by the insulating substrate 30, thus the thermistor 20 can be disposed on any position on the semiconductor chip 10, and also obtained is an effect that a degree of freedom of a layout design is increased. Described in the present embodiment is the example that the thermistor 20 is disposed on the first main electrode 11 of the semiconductor chip 10 as illustrated in FIG. 4, however, the thermistor 20 may also be disposed on an outer side of the first main electrode 11 as illustrated in FIG. 5, for example.

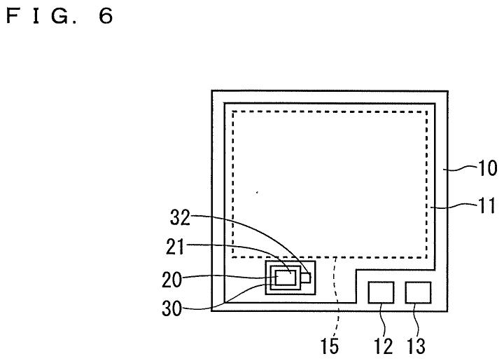

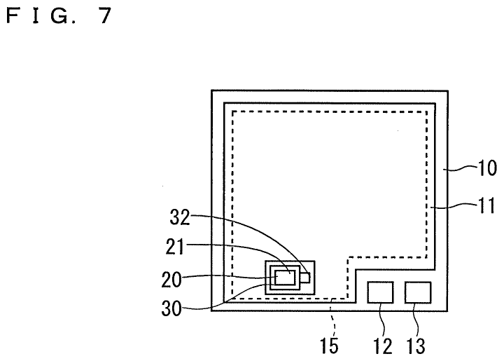

The thermistor 20 is not influenced by the current flowing in the first main electrode 11 of the semiconductor chip 10, thus the thermistor 20 needs not be disposed on an outer side of an effective region 15 of the semiconductor chip 10 where the semiconductor element is formed as illustrated in FIG. 6. That is to say, the effective region 15 of the semiconductor chip 10 may extend to a lower side of a position where the thermistor 20 is mounted as illustrated in FIG. 7. The effective region 15 extends to a lower side of the thermistor 20, thus internal resistance of the semiconductor chip 10 can be reduced, and heat generation can be suppressed. The state where the effective region 15 can extend indicates that, in other words, a size of the semiconductor chip 10 can be reduced while an area of the effective region 15 is maintained. Particularly, when SiC is used as the material of the semiconductor chip 10, the reduction of the size of the semiconductor chip 10 can significantly contribute to reduction of cost by reason that SiC is more expensive per unit area than Si.

The thermistor 20 is insulated from the semiconductor chip 10, thus even in a case where the semiconductor device according to the embodiment 1 is used for a circuit on a high voltage side of an inverter, the output signal of the thermistor 20 can be inputted to a circuit on a lower voltage side thereof (for example, an electronic control unit (ECU)) as it is without insulating the output signal by a coupler, for example. This configuration can contribute to prevention of transmission delay of the output signal of the thermistor 20 and reduction of a circuit area of the inverter.

### Embodiment 2

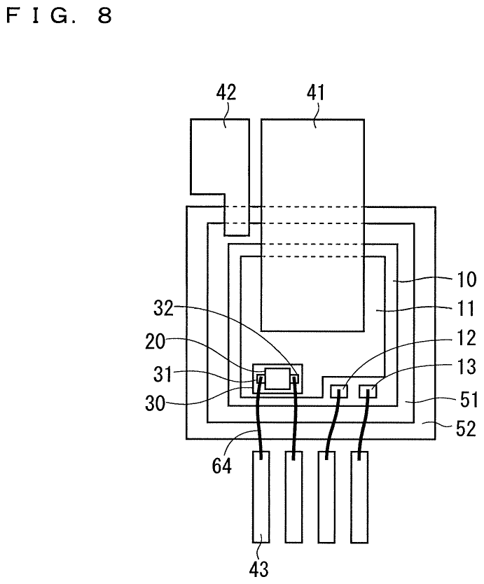

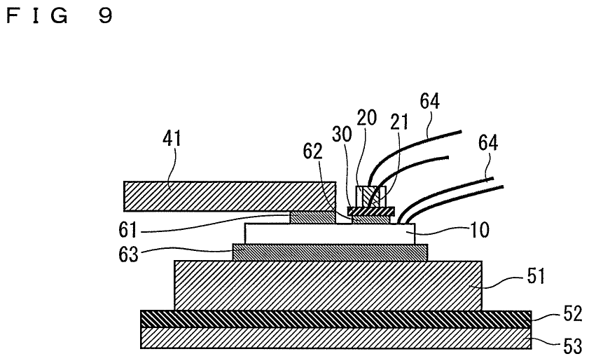

FIG. 8 and FIG. 9 are diagrams illustrating a configuration of a semiconductor device according to an embodiment 2. FIG. 8 is a plan view of the semiconductor device, and FIG. 9 is a side view of the semiconductor device. FIG. 3 illustrates an enlarged view of the thermistor 20 mounted on the insulating substrate 30 in the semiconductor device according to the embodiment 2.

In the embodiment 1, only the pattern wiring 32 connected to one (second electrode) of two electrodes included in the thermistor 20 is formed on the insulating substrate 30. In contrast, in the embodiment 2, a pattern wiring 31 connected to the first electrode 21 of the thermistor 20 and the pattern wiring 32 connected to the second electrode 22 of the thermistor 20 are formed on the insulating substrate 30. The aluminum wire 64 connected to the first electrode 21 is bonded to the pattern wiring 31, and the aluminum wire 64 connected to the second electrode 22 is bonded to the pattern wiring 32. The other configuration is similar to that of the embodiment 1.

According to the semiconductor device of the embodiment 2, the first electrode 21 and the second electrode 22 of the thermistor 20 are led outside of the thermistor 20 in a plan view by the pattern wiring 31 and the pattern wiring 32, respectively, and wire bonding can be performed on the first electrode 21 and the second electrode 22 using those pattern wiring 31 and pattern wiring 32 as the bonding pad. Such a configuration is effective in a case where it is difficult to directly perform wire bonding on the first electrode 21 and the second electrode 22 of the thermistor 20 such as a case where the thermistor 20 has the diameter smaller than the aluminum wire 64, for example.

### Embodiment 3

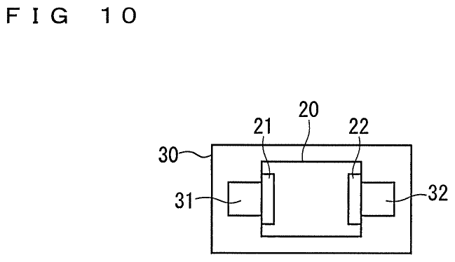

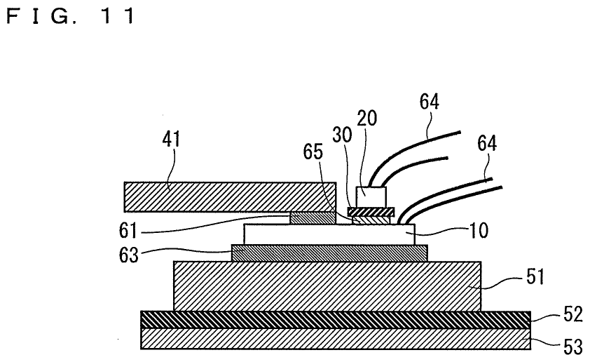

FIG. 11 is a diagram illustrating a configuration of the semiconductor device according to the embodiment 2, and illustrates a side view of the semiconductor device. A top view of the semiconductor device is similar to that in FIG. 2. The configuration of the insulating substrate 30 and the thermistor 20 may be any of that in FIG. 3 or FIG. 10.

In the embodiments 1 and 2, the insulating substrate 30 provided with the thermistor 20 and the semiconductor chip 10 are bonded to each other by the solder 62. In contrast, in an embodiment 3, the insulating substrate 30 and the semiconductor chip 10 are bonded by a bonding material 65 (referred to as “Ag bonding material 65” hereinafter) made of silver (Ag). The other configuration is similar to that of the embodiment 1 or 2.

Ag has low heat resistance, and has little concern of occurrence of void, for example, thus when the insulating substrate 30 and the semiconductor chip 10 are bonded to each other by the Ag bonding material 65, a measurement accuracy of the temperature of the semiconductor chip 10 can be increased.

The foregoing description is in all aspects illustrative, and it is therefore understood that numerous modifications not exemplified can be devised.

### EXPLANATION OF REFERENCE SIGNS

10 semiconductor chip, 11 first main electrode, 12 control electrode, 13 sensing electrode, 15 effective region, 20 thermistor, 21 first electrode, 22 second electrode, 30 insulating substrate, 31 pattern wiring, 32 pattern wiring, 41 first main terminal, 42 second main terminal, 43 signal terminal, 51 heat spreader, 52 insulating sheet, 53 metal foil, 61, 62, 63 solder, 64 aluminum wire, 65 Ag bonding material.

1. A semiconductor device, comprising:
a semiconductor chip; and
a thermistor mounted on the semiconductor chip, wherein
the thermistor is mounted on an insulating substrate bonded to the semiconductor chip, and the semiconductor chip and the thermistor are insulated from each other by the insulating substrate, and
formed on the insulating substrate is at least one pattern wiring leading an electrode of the thermistor outside of the thermistor in a plan view.

2. The semiconductor device according to claim 1, wherein
formed on the insulating substrate are the two pattern wirings leading two electrodes of the thermistor outside of the thermistor in a plan view, respectively.

3. The semiconductor device according to claim 1, wherein an effective region of the semiconductor chip extends to a lower side of a position where the thermistor is mounted.

4. The semiconductor device according to claim 1, wherein
the semiconductor chip is formed using SiC.

5. The semiconductor device according to claim 1, wherein
the semiconductor chip and the insulating substrate are bonded to each other by a bonding material containing Ag.

6. The semiconductor device according to claim 1, wherein
the insulating substrate is formed by AlN.
